(19) United States
(12) Patent Application Publication
(10) Pub. No.: US 2021/0175399 A1
(43) Pub. Date: Jun. 10, 2021

(54) PACKAGE FOR INSTALLING SEMICONDUCTOR ELEMENT, AND SEMICONDUCTOR DEVICE

(71) Applicant: PANASONIC INTELLECTUAL PROPERTY MANAGEMENT CO., LTD, Osaka (JP)

(72) Inventors: Ikuo NIWA, Kyoto (JP); Yasutaka HASE, Kyoto (JP); Shunsuke AKAI, Kyoto (JP); Hayato TAKAGI, Shiga (JP); Tomoyuki YOKOTA, Kyoto (JP); Hiroshi SANADA, Kyoto (JP)

(21) Appl. No.: 17/178,684

(22) Filed: Feb. 18, 2021

Related U.S. Application Data
(63) Continuation of application No. PCT/JP2019/034036, filed on Aug. 30, 2019.

(30) Foreign Application Priority Data
Aug. 31, 2018 (JP) 2018-163252

(51) Int. Cl. H01L 33/60; H01L 33/48; H01L 33/62

(52) U.S. Cl. CPC H01L 33/60; H01L 33/62; H01L 33/486

(57) ABSTRACT

A package for installing a semiconductor element includes: a lead frame; a resin frame disposed on the lead frame and including a housing portion formed by an opening that widens with the distance in the upward direction from the lead frame; and a metal reflector that fits in the housing portion and includes an opening portion corresponding to the housing portion of the resin frame. The opening area of the opening portion of the metal reflector increases with the distance in the upward direction from the lead frame, and the metal reflector includes a flange around the side of the metal reflector in which the opening area is large. The flange is placed on the top surface of the resin frame.

### CROSS REFERENCE TO RELATED APPLICATIONS

This application is a U.S. continuation application of PCT International Patent Application Number PCT/JP2019/034036 filed on Aug. 30, 2019, claiming the benefit of priority of Japanese Patent Application Number 2018-163252 filed on Aug. 31, 2018, the entire contents of which are hereby incorporated by reference.

### BACKGROUND

### 1. Technical Field

The present disclosure relates to an LED package, and in particular to a high-power and highly reliable LED package that is excellent in airtightness and heat dissipation, is corrosion resistant, and has high light extraction efficiency.

### 2. Description of the Related Art

Along with development of blue LED chips, for LED packages, there has been a need for phosphor-converted white LED packages. In addition, LED packages have ranged from those packages for small backlights of televisions, smartphones, cameras, in-vehicle instrument panels, and the like to large and high-power LED packages for LED lightings, in-vehicle headlights, and the like. Further in recent years, there have been increasing demands for infrared LEDs for face authentication or iris authentication on smartphones or PCs, night light sources for security systems such as surveillance cameras, or sensors of in-vehicle autonomous driving systems. Ultraviolet LEDs are also attracting attention for industrial applications or medical applications such as sterilization, or other applications such as replacement for mercury lamps.

Accordingly, there is a need in the market for low-cost, high-power, and highly reliable versatile packages that can be used for infrared LEDs or ultraviolet LEDs in addition to white LEDs.

### SUMMARY

In the case of ultraviolet LEDs and some of infrared LEDs, which have been demanded in the market in recent years, airtightness may be required. In this case, it is necessary to seal a portion where a semiconductor element is installed with a planar glass or a glass lens to secure the airtightness.

For example, in a configuration disclosed in Japanese Unexamined Patent Application Publication No. 2008-47916, lead frame 1622 and ring 134 are insert-molded into an integral part, and ring 134 is further covered with casing 122. Consequently, the configuration disclosed in Japanese Unexamined Patent Application Publication No. 2008-47916 requires using adhesive to join a planar glass or a glass lens. However, a problem with the configuration disclosed in Japanese Unexamined Patent Application Publication No. 2008-47916 is that it is difficult to secure airtightness because there is much less area for adhesive application on the planar glass or the glass lens due to the package construction.

Further, in the configuration disclosed in Japanese Unexamined Patent Application Publication No. 2008-47916, ring 134 is located at a lower position than a top plane of casing 122. Consequently, the inner area of ring 134 is constrained, which leads to another problem of being unable to secure sufficient reflection of light emitted from a light-emitting element.

Accordingly, a problem with the configuration disclosed in Japanese Unexamined Patent Application Publication No. 2008-47916 is that it is not possible to achieve a long-life, high-power, and highly reliable package for installing a semiconductor element.

The present disclosure provides a long-life, high-power, and highly reliable package for installing a semiconductor element.

A package for installing a semiconductor element according to an aspect of the present disclosure includes: a lead frame; a resin frame disposed on the lead frame and including a housing portion formed by an opening that widens with a distance in an upward direction from the lead frame; and a metal reflector that fits in the housing portion and includes an opening portion corresponding to the housing portion of the resin frame, wherein an opening area of the opening portion of the metal reflector increases with a distance in an upward direction from the lead frame, and the metal reflector includes a flange around a side of the metal reflector in which the opening area is large, and the flange is placed on a top surface of the resin frame.

According to this configuration, airtightness can be secured, and light extraction efficiency is satisfactory. In addition, the lead frame has satisfactory heat dissipation because the resin frame is molded so as to allow back side heat dissipation, and resin degradation can be prevented because a portion of the resin frame that is irradiated with light is covered with the metal reflector. In this way, a long-life, high-power, and highly reliable package for installing a semiconductor element can be provided.

Specifically, airtightness within the package for installing a semiconductor element can be secured by joining the flange placed on the top surface of the resin frame with a planar glass or a glass lens by Au/Sn sealing/bonding. In addition, since the metal reflector fitted in the housing portion of the resin frame covers further on the top surface of the resin frame that is irradiated with light, and it is easy to change the opening area on the side in which the opening area is small, optical design freedom is provided. Further, since the metal reflector is plated as optimal for a wavelength emitted from the semiconductor element, the light extraction efficiency is satisfactory, and resin degradation can be prevented. The configuration makes it possible to provide a long-life, high-power, and highly reliable package for installing a semiconductor element.

Furthermore, according to the configuration, since the flange is placed on the top surface of the resin frame, and the metal reflector is only needed to be placed on and joined to the resin frame, man-hours required for insert molding as with Japanese Unexamined Patent Application Publication No. 2008-47916 are eliminated and costs can be reduced.

Furthermore, a package for installing a semiconductor element according to an aspect of the present disclosure includes: a base substrate including pattern wiring; a ceramic frame disposed on the base substrate and including a housing portion formed by an opening that extends upward or widens with a distance in an upward direction from the base substrate; and a metal reflector that fits in the housing portion and includes an opening portion corresponding to the housing portion of the ceramic frame, wherein an opening area of the opening portion of the metal reflector increases with a distance in an upward direction from the base substrate, and the metal reflector includes a flange around a side of the metal reflector in which the opening area is large, and the flange is placed on a top surface of the ceramic frame.

According to this configuration, airtightness can be secured, and light extraction efficiency is satisfactory. In addition, the lead frame has satisfactory heat dissipation because the resin frame is molded so as to allow back side heat dissipation, and resin degradation can be prevented because a portion of the resin frame that is irradiated with light is covered with the metal reflector. In this way, a long-life, high-power, and highly reliable package for installing a semiconductor element can be provided.

Specifically, airtightness within the package for installing a semiconductor element can be secured by joining the flange placed on the top surface of the ceramic frame with a planar glass or a glass lens by Au/Sn sealing/bonding. In addition, since the metal reflector fitted in the housing portion of the ceramic frame covers further on the top surface of the ceramic frame that is irradiated with light, and it is easy to change the opening area on the side in which the opening area is small, optical design freedom is provided. Further, since the metal reflector is plated as optimal for a wavelength emitted from the semiconductor element, the light extraction efficiency is satisfactory. Therefore, the configuration makes it possible to provide a long-life, high-power, and highly reliable package for installing a semiconductor element.

The present disclosure can provide a long-life, high-power, and highly reliable package for installing a semiconductor element.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1A is a perspective view of a package for installing a semiconductor element of Example 1 according to the present disclosure.

FIG. 1B is a sectional view of a package for installing a semiconductor element of Example 1 according to the present disclosure.

FIG. 1C is a sectional view of a semiconductor device of Example 1 according to the present disclosure.

FIG. 2 is a sectional view for illustrating features of a metal reflector illustrated in FIG. 1B

FIG. 3 is a sectional view illustrating the amount of applied resin of Example 1 according to the present disclosure.

FIG. 4 is a sectional view of a package for installing a semiconductor element of Example 2 according to the present disclosure.

FIG. 5 is a sectional view illustrating a differently angled metallic reflecting surface of Example 4 according to the present disclosure.

FIG. 6A is a perspective view of a package for installing a semiconductor element of Example 5 according to the present disclosure.

FIG. 6B is a sectional view of a package for installing a semiconductor element of Example 5 according to the present disclosure.

FIG. 6C is a sectional view of a semiconductor device of Example 5 according to the present disclosure.

FIG. 7 is a sectional view of a package for installing a semiconductor element of Example 6 according to the present disclosure.

FIG. 8 is a sectional view of a package for installing a semiconductor element of Example 7 according to the present disclosure.

FIG. 9 is a sectional view of a package for installing a semiconductor element of Example 7 according to the present disclosure.

FIG. 10 is a sectional view of a package for installing a semiconductor element of Example 8 according to the present disclosure.

FIG. 11 is a sectional view of a package for installing a semiconductor element of Example 9 according to the present disclosure.

### DETAILED DESCRIPTION OF THE EMBODIMENTS

Hereinafter, specific examples of forms for implementing the present disclosure will be described in detail with reference to the Drawings. It should be noted that each of the following examples show a generic or specific example. The numerical values, shapes, materials, structural components, the arrangement and connection of the structural components, etc. shown in the following examples are mere examples, and thus are not intended to limit the present disclosure.

### Example 1

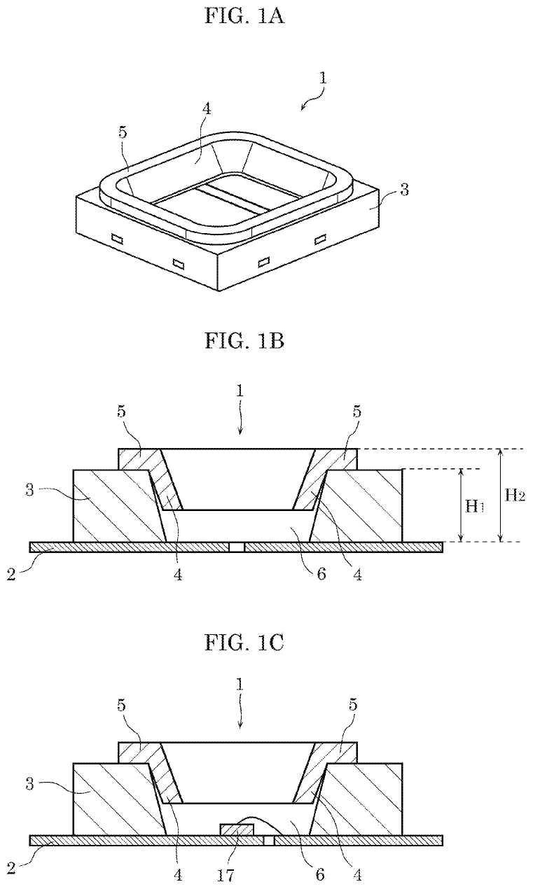

FIGS. 1A to 1C illustrate package 1 for installing a semiconductor element of Example 1 according to the present disclosure. FIG. 1A is a perspective view of package 1 for installing a semiconductor element of Example 1 according to the present disclosure. FIG. 1B is a sectional view of package 1 for installing a semiconductor element of Example 1 according to the present disclosure. FIG. 1C is a sectional view of a semiconductor device of Example 1 according to the present disclosure. Now that the overall picture of package 1 for installing a semiconductor element of Example 1 is grasped with reference to FIG. 1A, description will now be made with reference to the sectional view in FIG. 1B.

As illustrated in FIG. 1B, package 1 for installing a semiconductor element of Example 1 includes lead frame 2, resin frame 3 including housing portion 6, and metal reflector 4 including flange 5. Resin frame 3 is a specific example of a frame. More specifically, package 1 for installing a semiconductor element includes: lead frame 2; resin frame 3 disposed on lead frame 2 and including housing portion 6 formed by an opening that widens with a distance in the upward direction from lead frame 2; and metal reflector 4 that fits in housing portion 6 and includes an opening portion corresponding to housing portion 6 of resin frame 3. The opening area of the opening portion of metal reflector 4 increases with the distance in the upward direction from lead frame 2, and metal reflector 4 includes flange 5 around the side of metal reflector 4 in which the opening area is large, and flange 5 is placed on the top surface of resin frame 3.

Here, package 1 for installing a semiconductor element of Example 1 is characterized by flange 5 of metal reflector 4 being placed on the top surface of resin frame 3. Accordingly, height H₂ from the top surface of lead frame 2 to the topmost surface of flange 5 is higher than height H₁ from the top surface of lead frame 2 to the topmost surface of resin frame 3.

Now, airtightness may be required in some applications of products of ultraviolet LEDs and infrared LEDs.

In the package disclosed in Japanese Unexamined Patent Application Publication No. 2008-47916, the top surface of the product is covered with resin. Accordingly, the most suitable production practice is to use adhesive when joining a planar glass or a glass lens. However, it is difficult to secure airtightness because there is much less area for adhesive application on the planar glass or the glass lens due to the package construction. As a result, the package disclosed in Japanese Unexamined Patent Application Publication No. 2008-47916 may be a less reliable package.

On the other hand, in package 1 for installing a semiconductor element of Example 1, flange 5 of metal reflector 4 is placed on the top surface of resin frame 3. Accordingly, with Au plating on metal reflector 4 for example, Au/Sn sealing/bonding is available when joining the planar glass or the glass lens, and therefore it is possible to provide highly airtight and reliable package 1 for installing a semiconductor element. This is because Au atoms in Au plating provided on metal reflector 4 and Au atoms deposited on the planar glass or the glass lens move into Au/Sn solder in the interface, and then eutectic bonding occurs: in this way, an airtight joint can be attained even when the joined area is much smaller. Note that when planar glass or glass lens is not joined, an effect of dissipating heat of the package itself into the atmosphere is produced. For example, in the case in which an infrared LED is used for package 1 for installing a semiconductor element, radiation heat from the LED element can additionally be received by metal reflector 4 and dissipated from flange 5 into the atmosphere. In other words, even when no planar glass or glass lens is joined, Au plating on metal reflector 4 can provide package 1 for installing a semiconductor element that is excellent in heat dissipation.

Further in package 1 for installing a semiconductor element, it is possible to change the type or thickness of plating on metal reflector 4 to address highly reflective/high-power packages or highly reliable packages. In other words, metal reflector 4 may be provided with plating of Ag, Au, Ni, or Pd that has a thickness of 0.005 μm to 3.0 μm. Further, metal reflector 4 may be provided with Au plating that has a thickness of 0.08 μm to 0.1 μm. In the case of package 1 for installing a semiconductor element, for example, when lead frame 2 and/or metal reflector 4 of Cu alloy material are/is plated with highly thin Cu and with Ag having a thickness of 3.0 μm, a highly reflective/high-power package for a white LED can be provided. Additionally, for example, when lead frame 2 and/or metal reflector 4 of Cu alloy material are/is plated with an alloy containing Ni: 1.5 μm/Pd: 0.035 μm/Au: 0.005 μm and/or at least 51% of Au and at most 49% of Ag, a highly reliable package that is resistant to sulfuration and migration can be provided. This is because Ag is more prone to sulfuration and migration while Au is less prone to sulfuration and migration, and therefore sulfuration and migration can be prevented by reducing the Ag component and increasing the Au component, such as at least 51% of Au and at most 49% of Ag. Further in package 1 for installing a semiconductor element, for example, when lead frame 2 and/or metal reflector 4 of Cu alloy material are/is plated with Ni of 1.5 μm and Au of 0.1 μm, a high-power/highly reliable package that has high light extraction efficiency for an infrared LED can be provided. This is because Au is excellent in reflecting infrared light, and when the thickness is at least 0.08 μm, loss of infrared light due to transmission of the infrared light may be avoided, which improves reflectance and light extraction efficiency.

In package 1 for installing a semiconductor element, although a Cu alloy material, which can easily be subjected to plating and processing, and is excellent in heat dissipation, is used for the material of metal reflector 4, this is not a limitation. For the material of metal reflector 4, any metallic material optimal for the application of the product of package 1 for installing a semiconductor element may be specified. When the material of metal reflector 4 is, for example, an Al alloy material, which has high reflectance to ultraviolet light, such an Al alloy material is said to be the most suitable metallic material for the aforementioned ultraviolet LED package.

Note that in package 1 for installing a semiconductor element, all surfaces of metal reflector 4 that are fitted in housing portion 6 of resin frame 3 are metallic reflecting surfaces in order to provide optical design freedom and increase reflection of light. In addition, as illustrated in FIG. 1B, a bottom end of metal reflector 4 is located higher than a bottom surface of resin frame 3. This is because if the height of the bottommost of metal reflector 4 is not higher than the height of the bottommost of resin frame 3, an anode and a cathode of lead frame 2 would be short circuited.

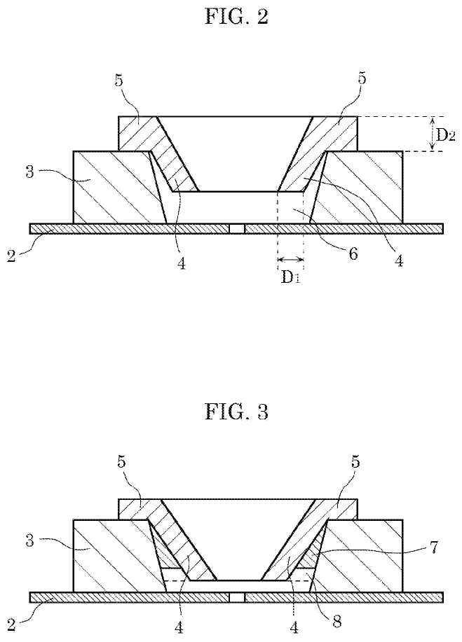

FIG. 2 is a sectional view for illustrating features of metal reflector 4 illustrated in FIG. 1B. Like elements as those in FIG. 1B are given the same reference characters.

As illustrated in FIG. 2, metal reflector 4 is characterized by first thickness D₁ of a portion that is fitted in housing portion 6 being thinner than second thickness D₂ of flange 5. Here, a value obtained by dividing first thickness D₁ by second thickness D₂ is at least 0.5 and at most 0.99. The value obtained by dividing first thickness D₁ by second thickness D₂ may be at least 0.9 and at most 0.99. As devised in this way, it is possible even with a small package to accommodate a high power product by increasing an area for installing a semiconductor element as much as possible. Further, as devised in this way, a required amount of metallic material can be reduced, which leads to cost reduction. However, in metal reflector 4, the value obtained by dividing first thickness D₁ of a portion that is fitted in housing portion 6 by second thickness D₂ of flange 5 needs to be at least 0.5. This is because the material of the portion that is fitted in housing portion 6 may move onto the top surface of flange 5 during processing of metal reflector 4, affecting flatness, which may cause a gap when sealingly bonding a planar glass or a glass lens and prevent airtightness from being maintained.

Next, joining of resin frame 3 and metal reflector 4 will be described with reference to FIG. 3. FIG. 3 is a sectional view illustrating the amount of applied resin of Example 1 according to the present disclosure.

Resin frame 3 and metal reflector 4 are joined with adhesive 7, instead of insert molding. In other words, in package 1 for installing a semiconductor element, resin frame 3 and metal reflector 4 are bonded with adhesive 7. In this way, resin frame 3 and metal reflector 4 are joined by a joining method that does not involve insert molding. As a result, the metallic reflecting surface fitted in housing portion 6 of resin frame 3 is free from contamination and foreign matters such as haze due to outgassing, so that the light extraction efficiency is satisfactory because reflectance reduction is eliminated. In addition, molding requires less man-hours, and therefore can be achieved at a low cost. Further, since resin frame 3 is covered with metal reflector 4, resin degradation can be prevented.

As described above, according to Example 1, a long-life, high-power, and highly reliable package 1 for installing a semiconductor element with resin degradation being prevented can be provided.

To improve reliability, however, it is important to control the amount of application of adhesive 7. This is because if a larger amount of adhesive 7 is applied and adhesive 7 reaches lead frame 2 beyond all bottom ends on a side of metal reflector 4 in which the opening area is small, adhesion of the semiconductor element installed on lead frame 2 is weakened, which may cause a risk of detachment of the element or wire bonding failure. Accordingly, to avoid the risk, package 1 for installing a semiconductor element of Example 1 includes region 8 in which adhesive 7 is not provided circumferentially on the side of metal reflector 4 in which the opening area is small. Specifically, in package 1 for installing a semiconductor element, as illustrated in FIG. 3, the amount of applied adhesive 7 is made in such a manner that region 8 in which adhesive 7 is not provided is included at the bottom end on the side of metal reflector 4 in which the opening area is small.

Next, in package 1 for installing a semiconductor element, light-emitting element 17 may be installed on the top surface of lead frame 2 in housing portion 6. In other words, as illustrated in FIG. 1C, once light-emitting element 17 is die-bonded to long-life, high-power, and highly reliable package 1 for installing a semiconductor element and subjected to wire bonding for electric conduction, a semiconductor device is completed. After that, according to product characteristics, a planar glass or a glass lens may be used for Au/Sn joint if airtightness is required or may only be potted with sealing resin.

Lead frame 2 may be made of a Cu alloy that has a thickness of 0.1 mm to 0.5 mm or may be a Cu alloy plated with Ag, Au, Pd, or the like. The material of resin frame 3 may be thermosetting resin or thermoplastic resin. The material of metal reflector 4 may be made from a base material of metal such as Cu and Al. Further, an oblique face of metal reflector 4 and oblique face of resin frame 3 may be analogous or non-analogous.

### Example 2

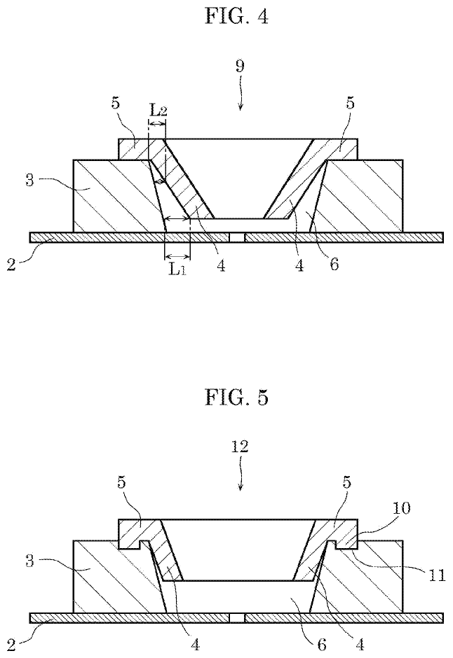

In Example 2 below, differences from Example 1 will mainly be described with reference to FIG. 4.

FIG. 4 is a sectional view of package 9 for installing a semiconductor element of Example 2 according to the present disclosure. Like elements as those in other figures such as FIG. 1B are given the same reference characters, and detailed description thereof will not be repeated.

As in Example 1, package 9 for installing a semiconductor element of Example 2 includes: lead frame 2; resin frame 3 disposed on lead frame 2 and including housing portion 6 formed by an opening that widens with the distance in the upward direction from lead frame 2; and metal reflector 4 that fits in housing portion 6 and includes an opening portion corresponding to housing portion 6 of resin frame 3. The opening area of the opening portion of metal reflector 4 increases with the distance in the upward direction from lead frame 2, and metal reflector 4 includes flange 5 around the side of metal reflector 4 in which the opening area is large, and flange 5 is placed on the top surface of resin frame 3.

Furthermore, in package 9 for installing a semiconductor element as illustrated in FIG. 4, in a region in which metal reflector 4 fits in housing portion 6, a first gap L₁ between resin frame 3 and a portion of metal reflector 4 on the side in which the opening area is small, is larger than a second gap L₂ between resin frame 3 and a portion of metal reflector 4 on the side in which the opening area is large.

In Example 2, in the case of metal reflector 4, first spacing L₁ between a portion of metal reflector 4 on the side in which the opening area is small and resin frame 3 can arbitrarily be varied within the size of housing portion 6 formed by an opening that widens with a distance in an upward direction in resin frame 3. In this way, it is possible to arbitrarily adjust the angle of the metallic reflecting surface of metal reflector 4 fitted into housing portion 6 of resin frame 3, so that light extraction efficiency can be maximized.

Meanwhile, for example, in the case of LEDs, different types of chips emit light in different ways, and chips may in some cases be given directivity depending on the application of the product. Even in such cases, package 9 for installing a semiconductor element is designed in such a manner that the angle of the metallic reflecting surface of metal reflector 4 fitted into housing portion 6 of resin frame 3 can be arbitrarily adjusted in order to maximize light extraction efficiency. In this way, high-power package 9 for installing a semiconductor element that has high light extraction efficiency suitable for any semiconductor element and any application of the product can be provided.

### Example 3

In Example 3 below, a bonding method of metal reflector 4 different from Example 1 and Example 2 will be described with reference to FIG. 1B.

As in Example 1, package 1 for installing a semiconductor element of Example 3 includes: lead frame 2; resin frame 3 disposed on lead frame 2 and including housing portion 6 formed by an opening that widens with the distance in the upward direction from lead frame 2; and metal reflector 4 that fits in housing portion 6 and includes an opening portion corresponding to housing portion 6 of resin frame 3. The opening area of the opening portion of metal reflector 4 increases with the distance in the upward direction from lead frame 2, and metal reflector 4 includes flange 5 around the side of metal reflector 4 in which the opening area is large, and flange 5 is placed on the top surface of resin frame 3.

Furthermore, in package 1 for installing a semiconductor element of Example 3, resin frame 3 and metal reflector 4 are in direct contact with each other.

Specifically, in Example 3, metal reflector 4 is fixed to resin frame 3 without adhesive. Such a joining method will be described below.

For example, in the case in which resin frame 3 is made of thermoplastic resin, metal reflector 4 may be fitted into resin frame 3 with metal reflector 4 heated at at least 300° C., although it is dependent on the resin material. As a result, surfaces of resin frame 3 melt, metal reflector 4 become tangled with the resin, and the resin is solidified when cooled, so that bonding can be achieved. The joining method is also referred to as welding. Since the joining method does not involve insert molding either, the metallic reflecting surface is free from contamination and foreign matters such as haze due to outgassing, so that the light extraction efficiency is satisfactory because reflectance reduction is eliminated. In addition, both molding and adhesive application require less man-hours, and therefore can be achieved at a low cost. Further, since resin frame 3 is covered with metal reflector 4, resin degradation can be prevented.

As described above, according to Example 3, a long-life, high-power, and highly reliable package 1 for installing a semiconductor element with resin degradation being prevented can be provided.

### Example 4

The structure of flange 5 of metal reflector 4 is not limited to the structure described in Example 1. In Example 4 below, description will be made, with reference to FIG. 5, as to the case in which metal reflector 4 that includes flange 5 of different structure as compared to Example 1 is provided. Differences from Example 1 will mainly be described below.

FIG. 5 is a sectional view illustrating a differently angled metallic reflecting surface of Example 4 according to the present disclosure. Like elements as those in other figures such as FIG. 1B are given the same reference characters, and detailed description thereof will not be repeated.

As in Example 1, package 12 for installing a semiconductor element of Example 4 includes: lead frame 2; resin frame 3 disposed on lead frame 2 and including housing portion 6 formed by an opening that widens with the distance in the upward direction from lead frame 2; and metal reflector 4 that fits in housing portion 6 and includes an opening portion corresponding to housing portion 6 of resin frame 3. The opening area of the opening portion of metal reflector 4 increases with the distance in the upward direction from lead frame 2, and metal reflector 4 includes flange 5 around the side of metal reflector 4 in which the opening area is large, and flange 5 is placed on the top surface of resin frame 3.

Furthermore, in package 12 for installing a semiconductor element, flange 5 includes protruding portion 10 in a bottom surface, resin frame 3 includes recessed portion 11 in the topmost surface, and protruding portion 10 engages with recessed portion 11.

This makes it possible for package 12 for installing a semiconductor element to position metal reflector 4. For example, in the case in which it is most suitable that the metallic reflecting surface of metal reflector 4 fitted into housing portion 6 of resin frame 3 has an angularly asymmetrical shape according to optical design, the positioning allows metal reflector 4 to be installed on resin frame 3 without reducing accuracy of optical characteristics due to misalignment. In addition, in the case of adhesive joint or welding with heat for the aforementioned thermoplastic resin material, bonding strength increases as the number of protruding portions 10 and recessed portions 11 respectively provided on the circumference increases when seen in top view, so that a highly reliable package 12 for installing a semiconductor element can be provided.

### Example 5

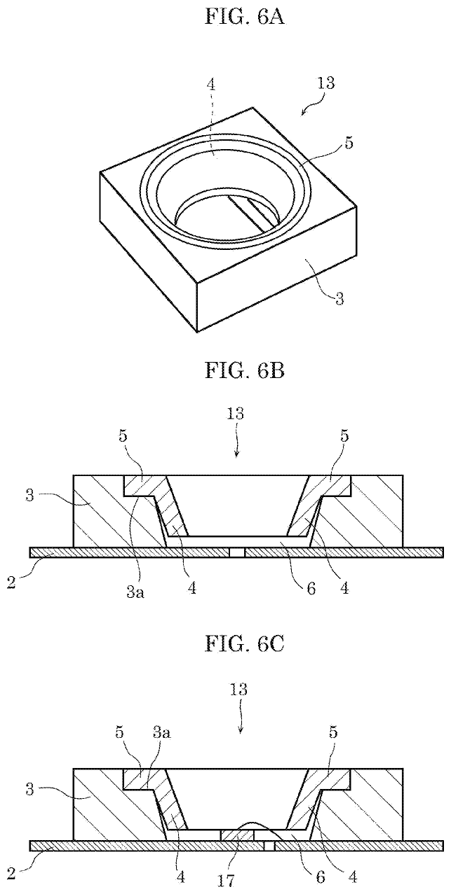

The structure of resin frame 3 as a frame is not limited to the structure described in examples such as Example 1. In Example 5 below, description will be made, with reference to FIGS. 6A to 6C, as to the case in which resin frame 3 of different structure as compared to examples such as Example 1 is provided. Differences from Example 1 will mainly be described below.

FIG. 6A is a perspective view of package 13 for installing a semiconductor element of Example 5 according to the present disclosure. FIG. 6B is a sectional view of a package for installing a semiconductor element of Example 5 according to the present disclosure. FIG. 6C is a sectional view of a semiconductor device of Example 5 according to the present disclosure. Now that the overall picture of package 13 for installing a semiconductor element of Example 5 is grasped with reference to FIG. 6A, description will now be made with reference to the sectional view in FIG. 6B.

Package 13 for installing a semiconductor element of Example 5 includes: lead frame 2; resin frame 3 disposed on lead frame 2 and including housing portion 6 formed by an opening that widens with the distance in the upward direction from lead frame 2; and metal reflector 4 that engages with the surface of housing portion 6 and includes an opening portion corresponding to housing portion 6 of resin frame 3. Resin frame 3 includes, on the side in which the opening area of the opening is large, first step 3a which is dug in from the topmost surface of resin frame 3. The opening area of the opening portion of metal reflector 4 increases with the distance in the upward direction from lead frame 2, and metal reflector 4 includes, around the side of metal reflector 4 in which the opening area is large, flange 5 that engages with first step 3a. Here, the height from the top surface of lead frame 2 to the topmost surface of resin frame 3 is the same as the height from the top surface of lead frame 2 to the topmost surface of metal reflector 4.

Specifically, in the case of package 13 for installing a semiconductor element, flange 5 is embedded in resin frame 3 as compared to package 1 for installing a semiconductor element described in Examples 1 to 4. Accordingly, low profile package 13 for installing a semiconductor element can be provided. As the era of lightness, thinness, shortness, and smallness continues still in the market, there is an increasing demand for reducing the height of a package for installing a semiconductor element. Package 13 for installing a semiconductor element can meet the demand.

In package 13 for installing a semiconductor element, since the height of the topmost surface of resin frame 3 and the height of the topmost surface of flange 5 is equivalent, a planar glass or a glass lens can be used for Au/Sn joint even when airtightness is required. Further, in package 13 for installing a semiconductor element, the joined area between resin frame 3 and metal reflector 4 with adhesive is extended, and therefore reliability of airtightness increases.

Note that, since package 13 for installing a semiconductor element has a common configuration to those such as package 1 for installing a semiconductor element illustrated in Examples 1 to 4, those effects described in Examples 1 to 4 are produced in a similar manner.

According to Example 5, accordingly, low-cost, long-life, high-power, and highly reliable package 13 for installing a semiconductor element of low profile that is excellent in both airtightness and heat dissipation can be provided.

In package 13 for installing a semiconductor element, light-emitting element 17 may be installed on the top surface of lead frame 2 in housing portion 6. In other words, as illustrated in FIG. 6C, once light-emitting element 17 is die-bonded to long-life, high-power, and highly reliable package 13 for installing a semiconductor element that is characterized by low profile and subjected to wire bonding for electric conduction, a semiconductor device is completed. After that, according to product characteristics, a planar glass or a glass lens may be used for Au/Sn joint if airtightness is required or may only be potted with sealing resin.

### Example 6

In Example 6 below, description will be made, with reference to FIG. 7, as to the case in which resin frame 3 of different structure as compared to Examples 1 to 5 is provided. Differences from examples such as Example 1 and Example 5 will mainly be described below.

FIG. 7 is a sectional view of package 14 for installing a semiconductor element of Example 6 according to the present disclosure. Like elements as those in other figures such as FIG. 1B and FIG. 6B are given the same reference characters, and detailed description thereof will not be repeated.

Package 14 for installing a semiconductor element of Example 6 includes: lead frame 2; resin frame 3 disposed on lead frame 2 and including housing portion 6 formed by an opening that widens with the distance in the upward direction from lead frame 2; and metal reflector 4 that engages with the surface of housing portion 6 and includes an opening portion corresponding to housing portion 6 of resin frame 3. Resin frame 3 includes, on the side in which the opening area of the opening is large, first step 3a which is dug in from the topmost surface of resin frame 3. The opening area of the opening portion of metal reflector 4 increases with the distance in the upward direction from lead frame 2, and metal reflector 4 includes, around the side of metal reflector 4 in which the opening area is large, flange 5 that engages with first step 3a. Here, the height from the top surface of lead frame 2 to the topmost surface of resin frame 3 is the same as the height from the top surface of lead frame 2 to the topmost surface of metal reflector 4.

Furthermore, in package 14 for installing a semiconductor element of Example 6, resin frame 3 includes, in the periphery of first step 3a, grooved portion 15 which is dug in the direction of lead frame 2, and metal reflector 4 includes, in the periphery of flange 5, second step 16 which is dug in from the topmost surface of flange 5.

Here, in package 14 for installing a semiconductor element, the adhesive may be provided in grooved portion 15 or the adhesive may be provided on second step 16. In this way, when resin frame 3 and metal reflector 4 are joined with adhesive, whether bonding is achieved can be determined at a glance once the adhesive is applied on the step (second step 16) of flange 5, so that it is possible to eliminate a risk of half adhesion. Further, since the adhesive is embedded in grooved portion 15 of resin frame 3, the combined bonding strength with the adhesive located on the step (second step 16) of the flange is further improved. In addition, grooved portion 15 of resin frame 3 functions to control the amount of applied adhesive. For example, when the amount of application is insufficient, grooved portion 15 is filled only in half, and when the amount of application is excessive, grooved portion 15 is filled entirely. In this way, the need of controlling accuracy of the amount of application is eliminated.

Note that, since package 14 for installing a semiconductor element has a common configuration to those such as package 1 for installing a semiconductor element illustrated in Examples 1 to 5, those effects described in Examples 1 to 5 are produced in a similar manner.

### Example 7

Although in Examples 1 to 6 above, as a specific example of a frame, description has been made with resin frame 3 taken as an example, this is not a limitation. The frame may be a ceramic frame.

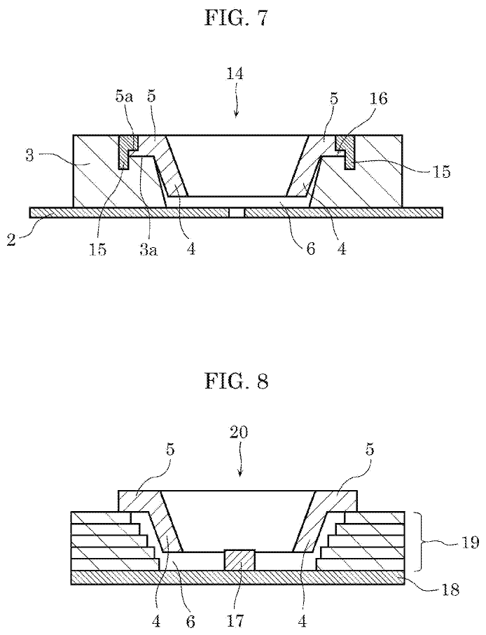

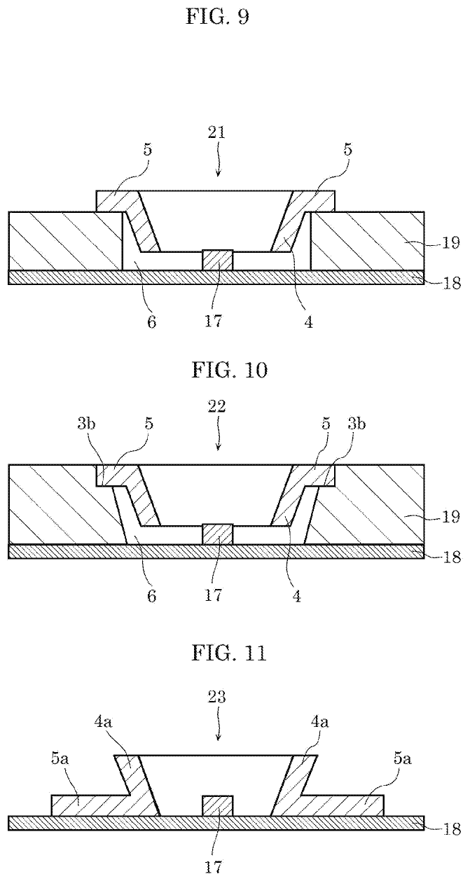

In Example 7 below, description will be made, with reference to FIG. 8 and FIG. 9, as to the case in which parts such as ceramic frame 19 are provided as a frame. Differences from Examples 1 to 6 will mainly be described below.

FIG. 8 is a sectional view of package 20 for installing a semiconductor element of Example 7 according to the present disclosure. FIG. 9 is a sectional view of package 21 for installing a semiconductor element of Example 7 according to the present disclosure. Like elements as those in other figures such as FIG. 1B are given the same reference characters, and detailed description thereof will not be repeated.

Package 21 or 20 for installing a semiconductor element of Example 7 includes: base substrate 18 including pattern wiring; ceramic frame 19 disposed on base substrate 18 and including housing portion 6 formed by an opening that extends upward or widens with the distance in the upward direction from base substrate 18; and metal reflector 4 that fits in housing portion 6 and includes an opening portion corresponding to housing portion 6 of ceramic frame 19. The opening area of the opening portion of metal reflector 4 increases with the distance in the upward direction from base substrate 19, and metal reflector 4 includes flange 5 around the side of metal reflector 4 in which the opening area is large, and flange 5 is placed on the top surface of ceramic frame 19.

In the case of ceramic frame 19 used in package 20 for installing a semiconductor element as illustrated in FIG. 8, housing portion 6 formed by an opening that widens with a distance in an upward direction from base substrate 18 is made by forming and firing a stack of thin ceramic sheets. Accordingly, as illustrated in FIG. 8, in the case of package 20 for installing a semiconductor element, the inside portion, namely a reflector portion, of ceramic frame 19 ends in a staircase-shaped surface when finished. A step of the staircase shape is of 10 μm to 100 μm including the precision of an application device, although even a 10-μm step may adversely affect reflection of light by causing irregular reflection or the like.

Accordingly, when a ceramic package is to be formed in general, it is often the case that, as seen in package 21 for installing a semiconductor element illustrated in FIG. 9 that is easy to be processed, the inside portion, namely a reflector portion of ceramic frame 19, is finished into surfaces perpendicular to base substrate 18. In the case of package 21 for installing a semiconductor element illustrated in FIG. 9, however, it is necessary to install a top-lit LED element because when an edge-lit LED element is installed, light extraction efficiency from housing portion 6 to the top surface is degraded. Accordingly, the range of selections of LED elements is limited.

Both in the case in which an edge-lit LED element is installed and the case in which a top-lit LED element is installed, it is necessary to secure sufficient luminous efficacy toward the top surface. To this end, as seen in package 20 for installing a semiconductor element illustrated in FIG. 8 and package 21 for installing a semiconductor element illustrated in FIG. 9, metal reflector 4 may be fitted into housing portion 6 located in the top surface of existing ceramic frame 19, without refabrication or conversion of the die.

In this way, by fitting metal reflector 4 in ceramic frame 19, high-luminance and high-power packages 20 and 21 for installing a semiconductor element that is tolerable to a temperature at least 250° C. can readily be provided, contrary to the case of resin frame 3.

Note that since the configuration in which metal reflector 4 is fitted in ceramic frame 19 is similar to the configuration in which metal reflector 4 is fitted in resin frame 3 as in Examples 1, 2, and 4, the effect produced when metal reflector 4 is fitted in ceramic frame 19 is also similar.

As described above, according to Example 7, since ceramic, which has high thermal conductivity, is used for the frame, it is possible to provide long-life, high-power, and highly reliable packages 20 and 21 for installing a semiconductor element in which airtightness can be secured with high light extraction efficiency and heat dissipation.

### Example 8

The structure of ceramic frame 19 as a frame is not limited to the structure described in examples such as Example 7. In Example 8 below, description will be made, with reference to FIG. 10, as to the case in which ceramic frame 19 of different structure as compared to examples such as Example 7 is provided. Differences from Example 7 will mainly be described below.

FIG. 10 is a sectional view of package 22 for installing a semiconductor element of Example 8 according to the present disclosure. Like elements as those in other figures such as FIGS. 1B to 9 are given the same reference characters, and detailed description thereof will not be repeated.

Package 22 for installing a semiconductor element of Example 8 includes: base substrate 18 having pattern wiring; ceramic frame 19 disposed on base substrate 18 and including housing portion 6 formed by an opening that extends upward or widens with the distance in the upward direction from base substrate 18; and metal reflector 4 that fits in housing portion 6 and includes an opening portion corresponding to housing portion 6 of ceramic frame 19. Ceramic frame 19 includes, in a region corresponding to the side of metal reflector 4 in which the opening area of the opening portion is large, first step 3b which is dug in from the topmost surface of ceramic frame 19. The opening area of the opening portion of metal reflector 4 increases with the distance in the upward direction from base substrate 18, and metal reflector 4 includes, around the side of metal reflector 4 in which the opening area is large, flange 5 that engages with first step 3b.

Although package 22 for installing a semiconductor element illustrated in FIG. 10 is illustrated as being provided with ceramic frame 19 that includes housing portion 6 formed by an opening that widens with a distance in an upward direction from base substrate 18, this is not a limitation. Package 22 for installing a semiconductor element illustrated in FIG. 8 may be provided with ceramic frame 19 that includes housing portion 6 formed by an opening composed of a surface perpendicular to base substrate 18.

In package 22 for installing a semiconductor element, as illustrated in FIG. 10, the height from the top surface of base substrate 18 to the topmost surface of ceramic frame 19 and the height from top surface of base substrate 18 to the topmost surface of metal reflector 4 are equivalent. In other words, in the case of package 22 for installing a semiconductor element, flange 5 is embedded in ceramic frame 19 as compared to packages 20 and 21 for installing a semiconductor element described in Example 7. In this way, low profile package 22 for installing a semiconductor element can be provided.

Note that since package 22 for installing a semiconductor element has a common configuration to packages 13 and 14 for installing a semiconductor element illustrated in Examples 5 and 6, those effects described in Examples 5 and 6 are produced in a similar manner.

As described above, according to Example 8, since ceramic, which has high thermal conductivity, is used for the frame, it is possible to provide long-life, high-power, and highly reliable package 22 for installing a semiconductor element in which airtightness can be secured with high light extraction efficiency and heat dissipation.

### Example 9

In Examples 1 to 8 above, although the package has been described as being provided with a frame, this is not a limitation. It is conceivable that the package is not provided with a frame.

In Example 9 below, description will be made, with reference to FIG. 11, as to the case in which the package is not provided with a frame. Differences from Examples 1 to 8 will mainly be described below.

FIG. 11 is a sectional view of package 23 for installing a semiconductor element of Example 9 according to the present disclosure. Like elements as those in other figures such as FIG. 1C and FIGS. 7 to 10 are given the same reference characters, and detailed description thereof will not be repeated.

Package 23 for installing a semiconductor element of Example 9 includes: base substrate 18 having pattern wiring; and metal reflector 4a that fits on base substrate 18. Metal reflector 4a includes flange 5a in a portion of metal reflector 4a that fits on base substrate 18. The opening area of an opening portion of metal reflector 4a increases with the distance in the upward direction from base substrate 18.

Meanwhile, in recent years, top-lit-type LED elements have been developed, and cost-effective products based on a frameless ceramic base substrate or a glass epoxy substrate on which an LED element is directly installed and only resin sealing is applied have been developed. In these products, however, the type of the LED element is limited to a top-lit light-emitting element of a flip-chip type, and therefore, selections of LED elements are less flexible.

On the other hand, in the case of package 23 for installing a semiconductor element of Example 9, by fitting metal reflector 4a on base substrate 18, it is possible not only to increase directivity for top emission but also to provide directivity for edge-lit LED elements of wire bonding type. Note that when an edge-lit LED element of wire bonding type is installed on package 23 for installing a semiconductor element, metal reflector 4a will contribute to preventing a wire from falling down. Accordingly, design freedom increases, which makes it possible to expand product lineups infinitely.

As described above, according to the present disclosure, airtightness is secured, and light extraction efficiency is satisfactory. In addition, the lead frame has satisfactory heat dissipation because the resin frame is molded so as to allow back side heat dissipation, and resin degradation can be prevented because a portion of the resin frame that is irradiated with light is covered with the metal reflector. Accordingly, a long-life, high-power, and highly reliable package for installing a semiconductor element can be provided.

According to the present disclosure, even when ceramics with high thermal conductivity are used, a long-life, high-power, and highly reliable package for installing a semiconductor element in which airtightness is secured with high light extraction efficiency and heat dissipation can be provided.

In this way, semiconductor devices that are versatile for infrared LEDs or ultraviolet LEDs in addition to white LEDs can be created.

Although packages for installing a semiconductor element according to one or more aspects of the present disclosure have been described thus far based on examples, the present disclosure is not limited to such examples. The one or more aspects of the present disclosure may thus include forms obtained by making various modifications to the above examples that can be conceived by those skilled in the art, as well as forms obtained by combining structural components in different embodiments, without materially departing from the spirit of the present disclosure.

### INDUSTRIAL APPLICABILITY

The present disclosure is applicable to packages for installing a semiconductor element and semiconductor devices, in particular, long-life, high-power, and highly reliable packages for installing a semiconductor element, and semiconductor devices that are versatile for infrared LEDs or ultraviolet LEDs in addition to white LEDs.

What is claimed is:

1. A package for installing a semiconductor element, comprising:
a lead frame;
a resin frame disposed on the lead frame and including a housing portion formed by an opening that widens with a distance in an upward direction from the lead frame; and
a metal reflector that fits in the housing portion and includes an opening portion corresponding to the housing portion of the resin frame, wherein
an opening area of the opening portion of the metal reflector increases with a distance in an upward direction from the lead frame, and the metal reflector includes a flange around a side of the metal reflector in which the opening area is large, and
the flange is placed on a top surface of the resin frame.

2. The package for installing a semiconductor element according to claim 1, wherein
a height from a top surface of the lead frame to a topmost surface of the flange is greater than a height from the top surface of the lead frame to a topmost surface of the resin frame.

3. The package for installing a semiconductor element according to claim 1, wherein
a plating of Ag or Au or Ni or Pd is provided on the metal reflector, the plating having a thickness of 0.005 μm to 3.0 μm.

4. The package for installing a semiconductor element according to claim 1, wherein
a bottom end of the metal reflector is located higher than a bottom surface of the resin frame.

5. The package for installing a semiconductor element according to claim 1, wherein
a first thickness of a portion of the metal reflector that fits in the housing portion is less than a second thickness of the flange.

6. The package for installing a semiconductor element according to claim 5, wherein
a value obtained by dividing the first thickness by the second thickness is at least 0.5 and at most 0.99.

7. The package for installing a semiconductor element according to claim 6, wherein
the value obtained by dividing the first thickness by the second thickness is at least 0.9 and at most 0.99.

8. The package for installing a semiconductor element according to claim 1, wherein
the resin frame and the metal reflector are joined using an adhesive.

9. The package for installing a semiconductor element according to claim 8, wherein
the metal reflector has, around a side of the metal reflector in which the opening area is small, a region in which the adhesive is not provided.

10. The package for installing a semiconductor element according to claim 1, wherein
in a region in which the metal reflector fits in the housing portion, a first gap between the resin frame and a portion of the metal reflector on a side in which the opening area is small is larger than a second gap between the resin frame and a portion of the metal reflector on the side in which the opening area is large.

11. The package for installing a semiconductor element according to claim 1, wherein
the resin frame and the metal reflector are in direct contact with each other.

12. The package for installing a semiconductor element according to claim 1, wherein
the flange includes a protruding portion in a bottom surface,
the resin frame includes a recessed portion in a topmost surface, and
the protruding portion engages with the recessed portion.

13. A package for installing a semiconductor element, comprising:
a lead frame;
a resin frame disposed on the lead frame and including a housing portion formed by an opening that widens with a distance in an upward direction from the lead frame; and
a metal reflector that engages with a surface of the housing portion and includes an opening portion corresponding to the housing portion of the resin frame, wherein
the resin frame includes a first step on a side in which an opening area of the opening is large, the first step being dug in from a topmost surface of the resin frame, and
an opening area of the opening portion of the metal reflector increases with a distance in an upward direction from the lead frame, and the metal reflector includes around a side of the metal reflector in which the opening area is large, a flange that engages with the first step.

14. The package for installing a semiconductor element according to claim 13, wherein
a height from a top surface of the lead frame to a topmost surface of the resin frame is same as a height from the top surface of the lead frame to a topmost surface of the metal reflector.

15. The package for installing a semiconductor element according to claim 13, wherein
the resin frame includes a grooved portion disposed in a periphery of the first step, the grooved portion being dug in a direction of the lead frame.

16. The package for installing a semiconductor element according to claim 15, wherein
the metal reflector includes a second step in a periphery of the flange, the second step being dug in from a topmost surface of the flange.

17. The package for installing a semiconductor element according to claim 15, wherein
an adhesive is provided in the grooved portion.

18. The package for installing a semiconductor element according to claim 16, wherein
an adhesive is provided in the second step.

19. A semiconductor device, comprising:
the package for installing a semiconductor element according to claim 1; and
a light-emitting element installed on the top surface of the lead frame, inside the housing portion.

20. A package for installing a semiconductor element, comprising:
a base substrate including pattern wiring;
a ceramic frame disposed on the base substrate and including a housing portion formed by an opening that extends upward or widens with a distance in an upward direction from the base substrate; and
a metal reflector that fits in the housing portion and includes an opening portion corresponding to the housing portion of the ceramic frame, wherein
an opening area of the opening portion of the metal reflector increases with a distance in an upward direction from the base substrate, and the metal reflector includes a flange around a side of the metal reflector in which the opening area is large, and
the flange is placed on a top surface of the ceramic frame.

21. A package for installing a semiconductor element, comprising:
a base substrate having pattern wiring;
a ceramic frame disposed on the base substrate and including a housing portion formed by an opening that extends upward or widens with a distance in an upward direction from the base substrate; and
a metal reflector that fits in the housing portion and includes an opening portion corresponding to the housing portion of the ceramic frame, wherein
the ceramic frame includes a first step in a region corresponding to a side of the metal reflector in which an opening area of the opening portion is large, the first step being dug in from a topmost surface of the ceramic frame, and
an opening area of the opening portion of the metal reflector increases with a distance in an upward direction from the base substrate, and the metal reflector includes, around a side of the metal reflector in which the opening area is large, a flange that engages with the first step.

22. A package for installing a semiconductor element, comprising:
a base substrate having pattern wiring; and
a metal reflector that fits on the base substrate, wherein
the metal reflector includes a flange in a portion of the metal reflector that fits on the base substrate, and an opening area of an opening portion of the metal reflector increases with a distance in an upward direction from the base substrate.
